(19) United States
(12) Patent Application Publication
(10) Pub. No.: US 2025/0335673 A1
(43) Pub. Date: Oct. 30, 2025

(54) PUMPING SYSTEM OPTIMIZATION SIMULATOR

(71) Applicant: Saudi Arabian Oil Company, Dhahran (SA)

(72) Inventors: Mutlaq Azimi, As Saffaniyah (SA); Hamad AIGhanim, As Saffaniyah (SA); Abduallah Alhussain, Al Hofuf (SA); Mohammed A. Alswayied, Riyadh (SA); Musaad M. Alosaimi, Al Aqrabiyah (SA)

(73) Assignee: Saudi Arabian Oil Company, Dhahran (SA)

(21) Appl. No.: 18/651,400

(22) Filed: Apr. 30, 2024

(51) Int. Cl. G06F 30/28

(52) U.S. Cl. CPC G06F 30/28

(57) ABSTRACT

A method and a system are disclosed. The method includes inputting pump system information such as a type of pipe, a length of pipe, a diameter of pipe, a type of pipe fittings, and a type of pipe valves. A pump performance data is obtained from a plurality of sources based on the pump system information. The method further includes obtaining a plurality of piping information based on the pump system information such as a material of pipe, a relative roughness of pipe, an effective area of pipe, and an equivalent length for the type of pipe fittings. A plurality of optimal system parameters is calculated based on a plurality of calculations based on the pump system information, the pump performance data, and the plurality of piping information. A maintenance operation is performed in response to the calculated plurality of optimal system parameters.

### BACKGROUND

Pumping systems play a vital role in various industries, influencing efficiency, energy consumption, and operational costs. The traditional pumping systems face challenges such as inefficient designs leading to pressure drops and suboptimal fluid flow between components. Optimizing the pumping systems enables enhancing efficiency, reducing operational costs, and mitigating potential equipment or system failure risks.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

Embodiments disclosed herein generally relate to a method, the method including inputting pump system information, the pump system information including a type of pipe, a length of pipe, a diameter of pipe, a type of pipe fittings, and a type of pipe valves and obtaining pump performance data from a plurality of sources based on the pump system information, the plurality of sources including sensor readings, operational parameters, and production rates. The method further includes obtaining a plurality of piping information based on the pump system information, wherein the plurality of piping information includes a material of pipe, a relative roughness of pipe, an effective area of pipe, and an equivalent length for the type of pipe fittings and calculating a plurality of optimal system parameters based on a plurality of calculations based on the pump system information, the pump performance data, and the plurality of piping information. A maintenance operation is performed in response to the calculated plurality of optimal system parameters.

Embodiments disclosed herein generally relate to a system. The system includes a plurality of sensors. The system further includes a computer processor coupled to the plurality of sensors. The computer processor includes functionality for inputting pump system information, the pump system information including a type of pipe, a length of pipe, a diameter of pipe, a type of pipe fittings, and a type of pipe valves and obtaining pump performance data from a plurality of sources based on the pump system information, the plurality of sources including sensor readings, operational parameters, and production rates. Further, a plurality of piping information is obtained based on the pump system information, wherein the plurality of piping information includes a material of pipe, a relative roughness of pipe, an effective area of pipe, and an equivalent length for the type of pipe fittings. A plurality of optimal system parameters is then calculated based on a plurality of calculations based on the pump system information, the pump performance data, and the plurality of piping information. Additionally, a maintenance operation is performed in response to the calculated plurality of optimal system parameters.

Embodiments disclosed herein generally relate to a non-transitory computer readable medium storing instructions executable by a computer processor. The instructions include functionality for inputting pump system information, the pump system information including a type of pipe, a length of pipe, a diameter of pipe, a type of pipe fittings, and a type of pipe valves and obtaining pump performance data from a plurality of sources based on the pump system information, the plurality of sources including sensor readings, operational parameters, and production rates. Further, a plurality of piping information is obtained based on the pump system information, wherein the plurality of piping information includes a material of pipe, a relative roughness of pipe, an effective area of pipe, and an equivalent length for the type of pipe fittings. A plurality of optimal system parameters is then calculated based on a plurality of calculations based on the pump system information, the pump performance data, and the plurality of piping information. Additionally, a maintenance operation is performed in response to the calculated plurality of optimal system parameters.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn are not necessarily intended to convey any information regarding the actual shape of the particular elements and have been solely selected for ease of recognition in the drawing.

FIG. 1 shows an exemplary pumping system in accordance with one or more embodiments of the present disclosure.

FIG. 2 shows an exemplary pumping system in accordance with one or more embodiments of the present disclosure.

FIG. 3 shows a flowchart in accordance with one or more embodiments of the present disclosure.

FIGS. 4A-4E shows examples of a user interface for acquiring input data according to embodiments of the present disclosure.

FIG. 5 shows a computer system in accordance with one or more embodiments of the present disclosure.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

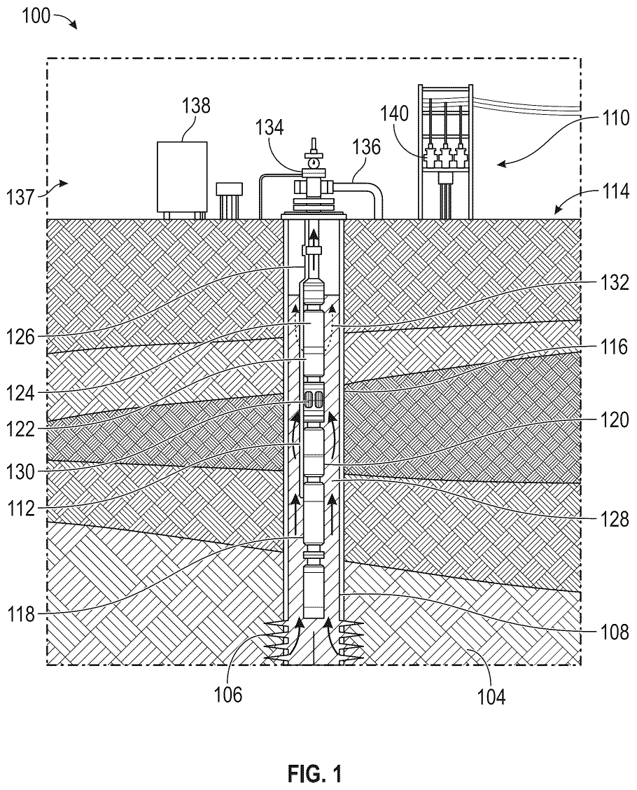

In the following description of FIGS. 1-4, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a horizontal beam” includes reference to one or more of such beams.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

Embodiments disclosed herein provide a method and system for optimizing a pumping system. Specifically, the method for operates an optimum number of pumps based on the system requirement, where all operating pumps are located within the operating region. Further, the method predicts the desired limit of the pump performance curve and predicts possible hydraulic issues in the pumping system. Additionally, the method extends the mean time between failures and reduces the power consumption required to operate pumps.

In one or more embodiments, this method may be implemented on already existing hardware packages as a plug-in module. The plug-in module may be deployed on the existing analytics setup. Initially the hardware package may be deployed as a standalone setup, with an interface provided to the driller to run Graphical User Interface (GUI). That ensures that the development and roll-out phase of the project are easier to implement, without requiring a permanent rig fixture. Alternatively, the system may be integrated directly to the pump system to perform a maintenance operation.

Additionally, a predictive maintenance may be performed based on the results of the simulation. Specifically, the predictive maintenance involves making decisions based on the analyzed data from the calculations and simulations and predicting a possible equipment failure, by studying the patterns and trends in the data. The predictive maintenance may help reduce the cost of maintenance by allowing for maintenance to be performed only when needed, rather than on a fixed schedule. Additionally, the predictive maintenance may help reduce unnecessary downtime and maintenance costs. By predicting equipment failure before it occurs, incidents may be prevented by allowing for timely maintenance or replacement of faulty equipment. The embodiments described in this disclosure may enable real-time monitoring of equipment performance, allowing for early detection of potential issues and faster response times.

FIG. 1 shows an exemplary pumping system (100) in accordance with one or more embodiments. The pumping system (100) is used to help produce produced fluids (102) from a formation (104). Perforations (106) in the well's (116) casing (108) provide a conduit for the produced fluids (102) to enter the well (116) from the formation (104). The pumping system (100) includes a surface portion having surface equipment (110) and a downhole portion having a string (112).

The string (112) is deployed in a well (116) on production tubing (117) and the surface equipment (110) is located on a surface location (114). The surface location (114) is any location outside of the well (116), such as the Earth's surface. The production tubing (117) extends to the surface location (114) and is made of a plurality of tubulars connected together to provide a conduit for produced fluids (102) to migrate to the surface location (114).

The string (112) may include a motor (118), motor protectors (120), a gas separator (122), a multi-stage centrifugal pump (124) (herein called a “pump” (124)), and a power cable (126). The string (112) may also include various pipe segments of different lengths to connect the components of the ESP string (112). The motor (118) is a downhole submersible motor (118) that provides power to the pump (124). The motor (118) may be a two-pole, three-phase, squirrel-cage induction electric motor (118). The motor's (118) operating voltages, currents, and horsepower ratings may change depending on the requirements of the operation.

The size of the motor (118) is dictated by the amount of power that the pump (124) requires to lift an estimated volume of produced fluids (102) from the bottom of the well (116) to the surface location (114). The motor (118) is cooled by the produced fluids (102) passing over the motor (118) housing. The motor (118) is powered by the power cable (126). The power cable (126) is an electrically conductive cable that is capable of transferring information. The power cable (126) transfers energy from the surface equipment (110) to the motor (118). The power cable (126) may be a three-phase electric cable that is specially designed for downhole environments. The power cable (126) may be clamped to the string (112) in order to limit power cable (126) movement in the well (116).

Motor protectors (120) are located above (i.e., closer to the surface location (114)) the motor (118) in the string (112). The motor protectors (120) are a seal section that houses a thrust bearing. The thrust bearing accommodates axial thrust from the pump (124) such that the motor (118) is protected from axial thrust. The seals isolate the motor (118) from produced fluids (102). The seals further equalize the pressure in the annulus (128) with the pressure in the motor (118). The annulus (128) is the space in the well (116) between the casing (108) and the ESP string (112). The pump intake (130) is the section of the ESP string (112) where the produced fluids (102) enter the ESP string (112) from the annulus (128).

The pump intake (130) is located above the motor protectors (120) and below the pump (124). The depth of the pump intake (130) is designed based off of the formation (104) pressure, estimated height of produced fluids (102) in the annulus (128), and optimization of pump (124) performance. If the produced fluids (102) have associated gas, then a gas separator (122) may be installed in the string (112) above the pump intake (130) but below the pump (124). The gas separator (122) removes the gas from the produced fluids (102) and injects the gas (depicted as separated gas (132) in FIG. 1) into the annulus (128). If the volume of gas exceeds a designated limit, a gas handling device may be installed below the gas separator (122) and above the pump intake (130).

The pump (124) is located above the gas separator (122) and lifts the produced fluids (102) to the surface location (114). The pump (124) has a plurality of stages that are stacked upon one another. Each stage contains a rotating impeller and stationary diffuser. As the produced fluids (102) enter each stage, the produced fluids (102) pass through the rotating impeller to be centrifuged radially outward gaining energy in the form of velocity.

The produced fluids (102) enter the diffuser, and the velocity is converted into pressure. As the produced fluids (102) pass through each stage, the pressure continually increases until the produced fluids (102) obtain the designated discharge pressure and has sufficient energy to flow to the surface location (114). The string (112) outlined in FIG. 1 may be described as a standard string (112), however, the term string (112) may be referring to a standard string (112) or an inverted string (112) without departing from the scope of the disclosure herein.

A packer is disposed around the string (112). Specifically, the packer is located above (i.e., closer to the surface location (114)) the multi-stage centrifugal pump (124). The packer may be any packer known in the art such as a mechanical packer. The packer seals the annulus (128) space located between the ESP string (112) and the casing (108). This prevents the produced fluids (102) from migrating past the packer in the annulus (128).

In other embodiments, sensors may be installed in various locations along the string (112) to gather downhole data such as pump intake volumes, discharge pressures, and temperatures. The number of stages is determined prior to installation based of the estimated required discharge pressure. Over time, the formation (104) pressure may decrease and the height of the produced fluids (102) in the annulus (128) may decrease. In these cases, the string (112) may be removed and resized. Once the produced fluids (102) reach the surface location (114), the produced fluids (102) flow through the wellhead (134) into production equipment (136). The production equipment (136) may be any equipment that can gather or transport the produced fluids (102) such as a pipeline or a tank.

The remainder of the pumping system (100) includes various surface equipment (110) such as electric drives (137) and pump system optimization simulator (138) as well as an electric power supply (140). The electric power supply (140) provides energy to the motor (118) through the power cable (126). The electric power supply (140) may be a commercial power distribution system or a portable power source such as a generator.

The pump system optimization simulator (138) is made up of an assortment of intelligent unit-programmable controllers and drives which maintain the proper flow of electricity to the motor (118) such as fixed-frequency switchboards, soft-start controllers, and variable speed controllers. The electric drives (137) may be variable speed drives which read the downhole data, recorded by the sensors, and may scale back or ramp up the motor (118) speed to optimize the pump (124) efficiency and production rate. The electric drives (137) allow the pump (124) to operate continuously and intermittently or be shut-off in the event of an operational problem.

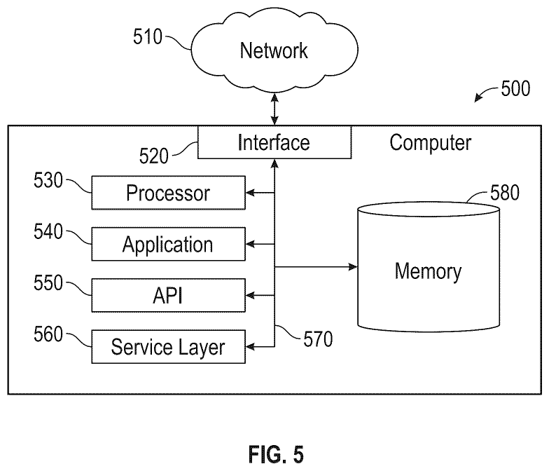

In one or more embodiments, the pump system optimization simulator (138) may include hardware and/or software with functionality for obtaining data, and performing one or more pump simulations. For example, the well status simulator (112) may store the historic data, operational parameters, production targets obtained by the sensors and inputted by the user. For this purpose, the generator may include memory with one or more data structures, such as a buffer, a table, an array, or any other suitable storage medium. The pump system optimization simulator (138) may further, at least, analyze the sensor readings, operational parameters, production targets, and user input to perform the calculations. While the pump system optimization simulator (138) is shown at a well site, in some embodiments, the pump system optimization simulator (138) may be located remotely from the well site. In some embodiments, pump system optimization simulator (138) may include a computer system that is similar to the computer system (500) described below with regard to FIG. 5 and the accompanying description.

Many pumping systems (100) require deep set packers where the pump (124) is set downhole from the packer. This requires a packer penetration system to be used to pass the power cable (126) of the pump (124) through the packer. The packer penetration system is a weak point in the pumping system (100) where a high percentage of pumping system (100) failures occur. Therefore, systems and methods that prevent the power cable from passing through the packer are beneficial. As such, embodiments disclosed herein present string (112) design that encapsulates the motor (118) and allows the electrical connections between the power cable (126) and the motor (118) to occur in an environment absent of produced fluids (102) using a motor head.

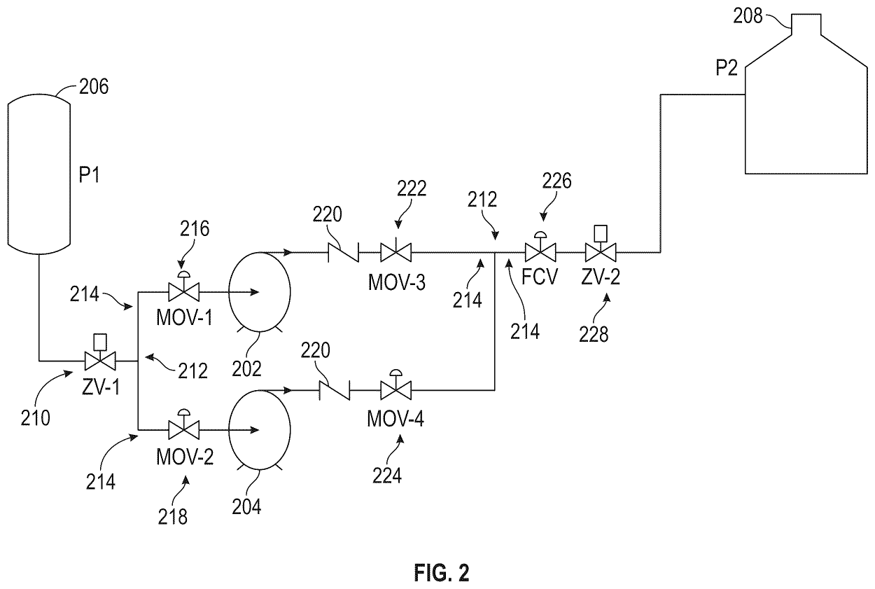

FIG. 2 shows an exemplary pump system (200) in accordance with one or more embodiments. Specifically, the pump system (200) includes two parallel pumps (202, 204). However, in some embodiments, the number of pumps may vary. The parallel pump system (202, 204) may involve multiple pumps operating simultaneously to improve efficiency and provide redundancy, in case one of the pumps becomes inoperable. Specifically, if one of the pumps fails, other pumps ensure continuous operation.

In one or more embodiments, the pump system (200) may employ centrifugal pumps, which are able to process various liquids. The centrifugal pumps operate by converting rotational energy, supplied by a motor, to a kinetic energy which moves the liquid through the system. In the parallel pump system, the pumps may be synchronized to work together by extracting liquid from an upstream tank (206) through the upstream suction vessel and pushing it into the downstream tank (208). In some embodiments, the pumps may have a same flow rate, pressure, and different performance parameters to ensure a balanced operation. Alternatively, each pump may operate separately.

In one or more embodiments, the piping design of the suction vessel may include a safety isolation valve (210). The safety isolation valve (210) is connected to the tank with pipes and it safeguards the pump system. Specifically, the safety isolation valve enables the shutdown of the pump system and separates it from the rest of the system in a case of emergency. The safety isolation valve (210) is designed to prevent the backflow of the liquids, so that the liquids do not flow back into the pumps or the upstream suction vessel when the pump system is inactive.

The safety isolation valve (210) may be connected to the pumps (202, 204) through one T-joint (212), two 90-degree elbows (214), and motor operated valves (216, 218). The motor operated valves (216, 218) are controlled by the motors and enable a remote control of the flow process and regulation of the liquid flow into the pumps (202, 204). Further, the motor operated valves (216, 218) are ensuring a balanced flow rate to the pumps (202, 204) to prevent overflowing or insufficient intake of the liquids.

In one or more embodiments, on the discharge side the check valves (220) are regulating the flow direction of the liquid, by ensuring that the liquid flows from the suction vessel to the downstream tank. Additionally, the check valves (220) regulate the pressure in the system and improve the efficiency of the system. The check valves (220) are connected to the motor operated valves (222, 224), which are connected through one T-joint (212) and two 90-degree elbows (214) to a globe valve (226). The globe valve (226) provides a more precise control over the flow by modulating the opening of the valve. The globe valve (226) is further connected to the downstream tank (208) through the safety isolation valve (228).

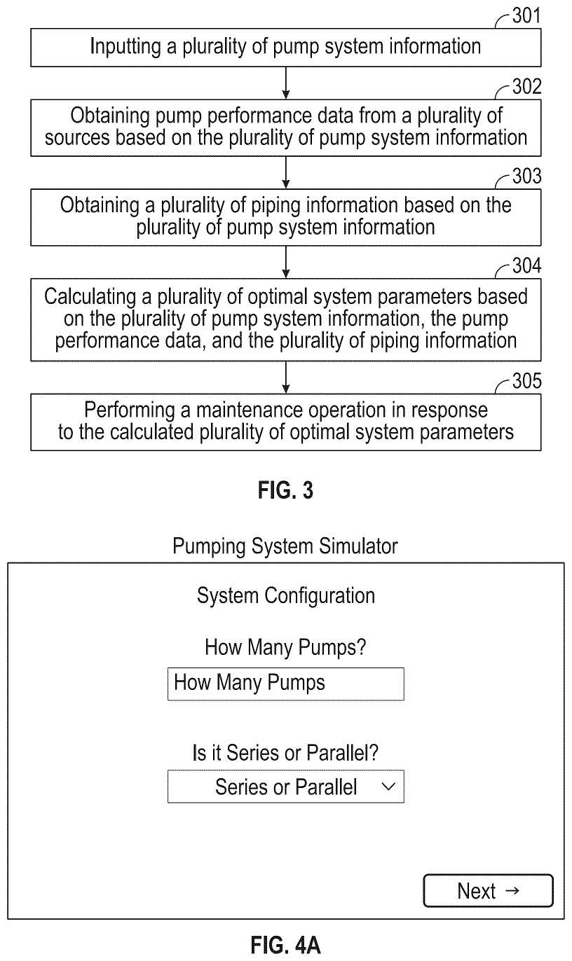

FIG. 3 shows a flowchart for a pumping system optimization in accordance with one or more embodiments. Specifically, in Block 301, a plurality of pump system information is inputted into a pumping system optimization simulator (138) by a user. In some embodiments, the pump system information includes, at least, characteristics of pipe, a pump curve, an elevation difference, and required flow.

In one or more embodiments, the characteristics of the pipe may include, at least, dimensions, a pressure rating, rigidity, temperature resistance, and a material composition such as PVC, steel, copper, or variety of alloys where each material may have different durability and corrosion resistance and can be used for a specific liquid. The pump curve represents performance of the pump and may include a flow rate, a total dynamic head pressure exerted by the pump on to the liquids, and efficiency of the pump for converting motor power into hydraulic power.

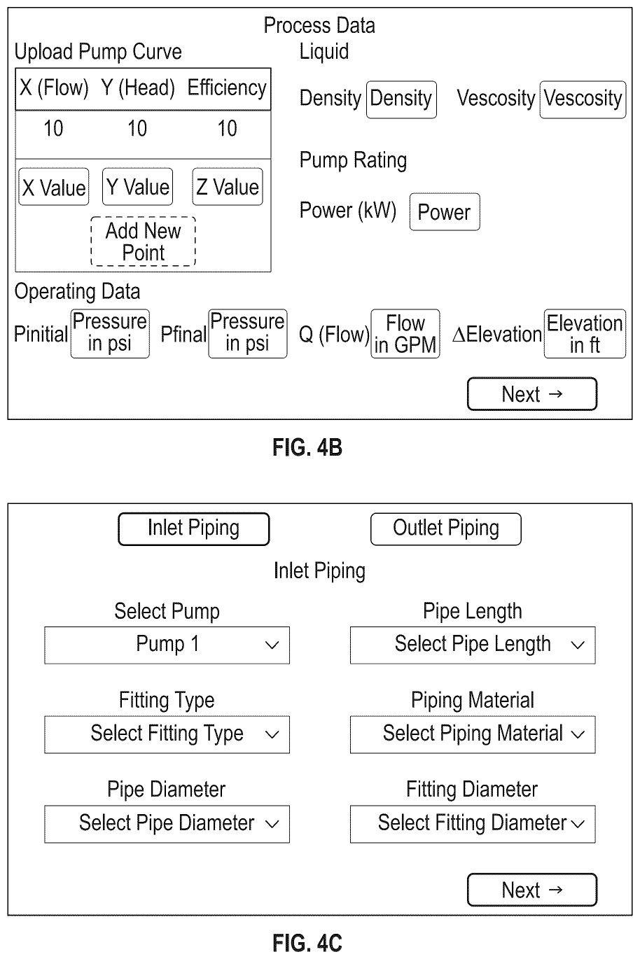

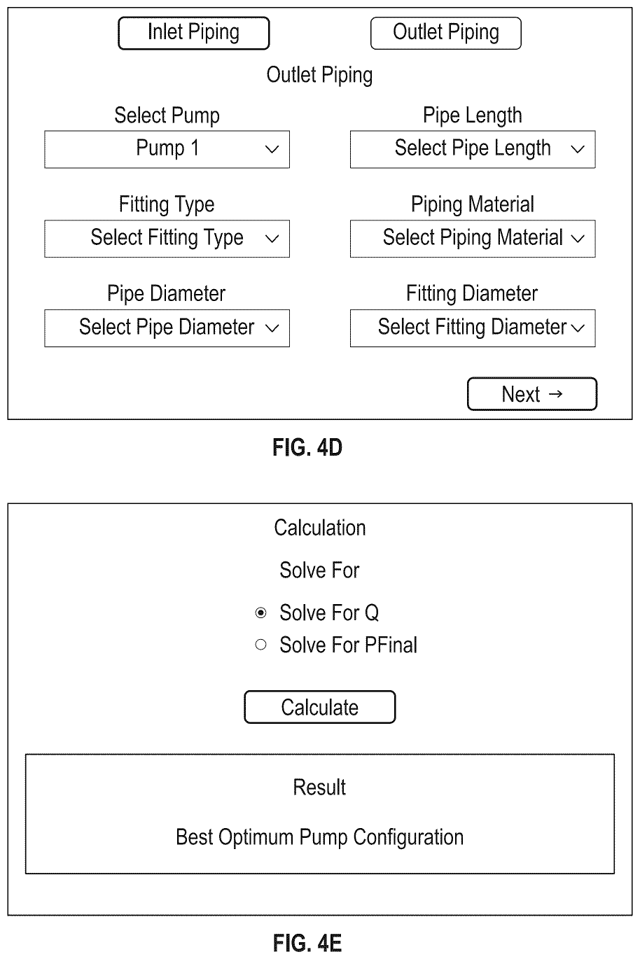

FIGS. 4A-E show examples of a user interface for acquiring input data for a pump system configuration. The user interface may be implemented on any suitable computing device, as shown in FIG. 5, and displayed on a display. A system operator may interact with the user interface and input the pump system configuration. Specifically, FIG. 4A requires the user to input the number of pumps and whether the pumps are connected in parallel or in series. Further, FIG. 4B requires inputting the pump curve parameters such as the flow rate, the pressure, and the efficiency of the pump. Further, FIG. 4B requires density and viscosity of the liquid and the pump power rating. In some embodiments, the operational parameters such as initial and final pressure, flow, and elevation may be inputted by the user. Alternatively, the operational parameters may be obtained from the plurality of sensors, as described in Block 302.

FIGS. 4C and 4D show inputting the inlet and outlet piping parameters. The input piping represents the suction side of the pump system, and the outlet piping represents the discharge side of the pump system. Specifically, various parameters such as fitting type, pipe diameter, pipe length, piping material, and fitting diameter may be recorded for each pump in the system. Further, FIG. 4E prompts the operator to select one or more optimal system parameters to be calculated by the system.

Returning to FIG. 3, in Block 302, the pump performance data is obtained from a plurality of sources. Specifically, the data may include inputs such as sensor readings, operational parameters, production targets, etc. In one or more embodiments the sensor readings, the operational parameters, and production targets may be obtained in real-time. In other embodiments, the sensor readings, the maintenance records, the operational parameters, and production targets may be obtained sequentially or immediately after drilling operations are performed.

The sensor readings may include data regarding a plurality of pump performance parameters. The data regarding the plurality of pump performance parameters includes, at least, the data about pressure, temperature, and flow rate. The sensor readings may be obtained using specialized tools such as, as least, thermometers, pressure gauges, and flowmeters (e.g., venturi meters, turbine meters, ultrasonic meters, electromagnetic meters, etc.). The operational parameters include data about time of the equipment's operation, load of the equipment, and speed of the equipment. Further, the production targets include data on expected performance of the equipment.

In Block 303, a plurality of piping information is obtained based on the pump system information. The piping information may be stored in a library and include, at least, a material of pipe, a relative roughness of pipe, an effective area of pipe, and an equivalent length for the type of pipe fittings. The relative roughness of pipe represents a ratio between roughness of an inner surface of the pipe and the pipe diameter and helps with determining frictional losses within the pipe. Further, the effective area of the pipe is a cross-sectional area through which the fluid flows within the pipe. The data stored in the library may be obtained based on matching the pump system information with the corresponding data stored in the library.

In one or more embodiments, the data obtained and inputted in Blocks 301-303 may vary between the embodiments. Specifically, certain parameters may be inputted by the user in one embodiment, obtained by the sensors in second embodiment, and obtained from the library in third embodiment.

In Block 304, a plurality of calculations are performed based on the plurality of pump system information, the pump performance data, and the plurality of piping information. Specifically, the pumping system optimization simulator (138) utilizes the input data and obtained data to calculate the optimum system parameters that include a final pressure in the system and a volumetric flowrate. To calculate the final pressure in the system and the volumetric flowrate formulas such as Reynolds number equation, Shacham equation, Hagen-Poiseuille equation, and Energy equation may be used.

As the first step, Reynolds number equation (Equation 1) calculates the Reynold number (Re) which determines whether the flow is laminar, transitional, or turbulent based on the ratio of inertial forces to viscous forces.

$$Re = \frac{ρ * v * D}{μ} \qquad ( Equation 1 )$$

Where μ represents viscosity.

The Reynolds number is inputted into the Shecham equation (Equation 2) which calculates the friction factor (f_{F}) and provides an estimation of pressure drop based on flow conditions, pipe geometry, and fluid properties.

$${f}_{F} = {\{ - 1.7 \; 37 ln [ 0.269 \frac{ε}{D} - \frac{2.185}{Re} ln ( 0.269 \frac{ε}{D} + \frac{14.5}{Re} ) ] \}}^{- 2} \qquad ( Equation 2 )$$

Where ε represents the effective surface roughness.

Further, Hagen-Poiseuille equation (Equation 3) is used to calculate the friction losses ( [symbol] ) and determine a pressure drop or rate of flow of a liquid, due to viscous forces, through the pipe system with a laminar flow.

$$= \frac{32 * {f}_{F} * {Q}^{2} * L}{{π}^{2} * {D}^{5}} \qquad ( Equation 3 )$$

Where Q represents the volumetric flowrate, L represents the length of the pipe, and D represents the diameter of the pipe.

The frictional loss is inputted into the energy equation (Equation 4) which considers the conservation of energy in a fluid through the flow system by incorporating potential energy, kinetic energy, and pressure energy. The energy equation enables determining pressure changes along the pump system. For the volumetric rate, it is represented as a velocity term in the Reynolds number and energy equation, thus iteration method is used to solve for the velocity.

$$g Δ Z + \frac{Δ P}{ρ} + + {W}_{p} + Δ \frac{{v}^{2}}{2} = 0 \qquad ( Equation 4 )$$

Where g represents the gravitational constant, ΔZ represents the elevation change, ΔP represents the differential pressure, ρ represents the density of the liquid, [symbol] represents the frictional losses, and v represents the velocity.

In Block 305, a maintenance operation is carried out, after calculating the final pressure and the volumetric rate. Specifically, when the final pressure and the volumetric rate indicate that the system is defected, the maintenance operation may include, at least, refurbishing equipment components and replacing damaged or worn-out wellbore components. In another example, the maintenance operation may include transmitting an electronic signal sent to an automated maintenance system for procuring and delivering pump system equipment components to a system site for performing a maintenance operation of replacing or refurbishing the pump system equipment components.

Specifically, a variety of maintenance procedures involve specific, tangible actions that are carried out on the pump equipment, and the variety of maintenance procedures are based on the final pressure and the volumetric rate calculations. A preventive maintenance may involve performing routine checks and inspections of the equipment to identify any potential issues before they lead to equipment failure. This may include checking the integrity of the valves, inspecting the condition of the pipes and fittings, and assessing the performance of the pumps and motors, etc.

Additionally, the statistical analysis prediction may also trigger predictive maintenance procedures, such as using the final pressure and the volumetric rate calculations to forecast when specific components of the pump equipment are likely to fail and scheduling maintenance activities accordingly. This can help to minimize downtime and optimize the overall efficiency of the oil production process. Further, the ensemble prediction may lead to corrective maintenance operation and to optimizing the number of pumps that may be supported by the system. If the ensemble prediction indicates a high likelihood of equipment failure, corrective actions such as repairing or replacing faulty components could be taken immediately to prevent the predicted failure.

The final pressure and the volumetric rate calculations may also trigger a condition-based maintenance, where maintenance tasks are only performed when certain indicators show signs of decreasing performance or upcoming failure. This involves monitoring the real-time condition of the pump equipment and performing maintenance activities based on the current state of the equipment.

In some embodiments, the final pressure and the volumetric rate calculations could be used to implement a maintenance operation. If the statistical analysis prediction indicates a potential equipment failure, a remote-control system could be used to adjust the operating parameters of the pump system equipment to prevent the failure. This could include adjusting the volumetric flow rate, pressure, or temperature to maintain the optimal operating conditions for the equipment.

Embodiments disclosed herein may be implemented on any suitable computing device, such as the computer system shown in FIG. 5. The pumping system optimization simulator is integrated to the computer system by being installed as a software to the computing device. Further, FIG. 5 is a block diagram of a computer system (500) used to provide computational functionalities associated with described algorithms, methods, functions, processes, flows, and procedures as described in the instant disclosure, according to an implementation. The illustrated computer (500) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (500) may include a computer that includes an input device, such as a keypad, keyboard, touch screen, or other device that can accept user information, and an output device that conveys information associated with the operation of the computer (500), including digital data, visual, or audio information (or a combination of information), or a GUI.

The computer (500) can serve in a role as a client, network component, a server, a database or other persistency, or any other component (or a combination of roles) of a computer system for performing the subject matter described in the instant disclosure. The illustrated computer (500) is communicably coupled with a network (510). In some implementations, one or more components of the computer (500) may be configured to operate within environments, including cloud-computing-based, local, global, or other environment (or a combination of environments).

At a high level, the computer (500) is an electronic computing device operable to receive, transmit, process, store, or manage data and information associated with the described subject matter. According to some implementations, the computer (500) may also include or be communicably coupled with an application server, e-mail server, web server, caching server, streaming data server, business intelligence (BI) server, or other server (or a combination of servers).

The computer (500) can receive requests over network (510) from a client application (for example, executing on another computer (500) and responding to the received requests by processing the said requests in an appropriate software application. In addition, requests may also be sent to the computer (500) from internal users (for example, from a command console or by other appropriate access method), external or third-parties, other automated applications, as well as any other appropriate entities, individuals, systems, or computers.

Each of the components of the computer (500) can communicate using a system bus (570). In some implementations, any or all of the components of the computer (500), both hardware or software (or a combination of hardware and software), may interface with each other or the interface (520) (or a combination of both) over the system bus (570) using an application programming interface (API) (550) or a service layer (560) (or a combination of the API (550) and service layer (560). The API (550) may include specifications for routines, data structures, and object classes. The API (550) may be either computer-language independent or dependent and refer to a complete interface, a single function, or even a set of APIs. The service layer (560) provides software services to the computer (500) or other components (whether or not illustrated) that are communicably coupled to the computer (500). The functionality of the computer (500) may be accessible for all service consumers using this service layer. Software services, such as those provided by the service layer (560), provide reusable, defined business functionalities through a defined interface. For example, the interface may be software written in JAVA, C++, or other suitable language providing data in extensible markup language (XML) format or other suitable format. While illustrated as an integrated component of the computer (500), alternative implementations may illustrate the API (550) or the service layer (560) as stand-alone components in relation to other components of the computer (500) or other components (whether or not illustrated) that are communicably coupled to the computer (500). Moreover, any or all parts of the API (550) or the service layer (560) may be implemented as child or sub-modules of another software module, enterprise application, or hardware module without departing from the scope of this disclosure.

The computer (500) includes an interface (520). Although illustrated as a single interface (520) in FIG. 5, two or more interfaces (520) may be used according to particular needs, desires, or particular implementations of the computer (500). The interface (520) is used by the computer (500) for communicating with other systems in a distributed environment that are connected to the network (510). Generally, the interface (520 includes logic encoded in software or hardware (or a combination of software and hardware) and operable to communicate with the network (510). More specifically, the interface (520) may include software supporting one or more communication protocols associated with communications such that the network (510) or interface's hardware is operable to communicate physical signals within and outside of the illustrated computer (500).

The computer (500) includes at least one computer processor (530). Although illustrated as a single computer processor (530) in FIG. 5, two or more processors may be used according to particular needs, desires, or particular implementations of the computer (500). Generally, the computer processor (530) executes instructions and manipulates data to perform the operations of the computer (500) and any algorithms, methods, functions, processes, flows, and procedures as described in the instant disclosure.

The computer (500) also includes a memory (580) that holds data for the computer (500) or other components (or a combination of both) that can be connected to the network (510). For example, memory (580) can be a database storing data consistent with this disclosure. Although illustrated as a single memory (580) in FIG. 5, two or more memories may be used according to particular needs, desires, or particular implementations of the computer (500) and the described functionality. While memory (580) is illustrated as an integral component of the computer (500), in alternative implementations, memory (580) can be external to the computer (500).

The application (540) is an algorithmic software engine providing functionality according to particular needs, desires, or particular implementations of the computer (500), particularly with respect to functionality described in this disclosure. For example, application (540) can serve as one or more components, modules, applications, etc. Further, although illustrated as a single application (540), the application (540) may be implemented as multiple applications (540) on the computer (500). In addition, although illustrated as integral to the computer (500), in alternative implementations, the application (540) can be external to the computer (500).

There may be any number of computers (500) associated with, or external to, a computer system containing computer (500), each computer (500) communicating over network (510). Further, the term “client,” “user,” and other appropriate terminology may be used interchangeably as appropriate without departing from the scope of this disclosure. Moreover, this disclosure contemplates that many users may use one computer (500), or that one user may use multiple computers (500).

In some embodiments, the computer (500) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AlaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method comprising:
inputting, using a computer processor, pump system information, the pump system information including a type of pipe, a length of pipe, a diameter of pipe, a type of pipe fittings, and a type of pipe valves;
obtaining, using the computer processor, pump performance data from a plurality of sources based on the pump system information, the plurality of sources including sensor readings, operational parameters, and production rates;
obtaining, using the computer processor, a plurality of piping information based on the pump system information, wherein the plurality of piping information includes a material of pipe, a relative roughness of pipe, an effective area of pipe, and an equivalent length for the type of pipe fittings;
calculating, using the computer processor, a plurality of optimal system parameters based on a plurality of calculations based on the pump system information, the pump performance data, and the plurality of piping information; and
performing, using the computer processor, a maintenance operation in response to the calculated plurality of optimal system parameters.

2. The method of claim 1, wherein calculating the plurality of optimal system parameters comprises:
determining, using the computer processor, a laminar flow of liquid using Reynolds number equation;
calculating, using the computer processor, a pressure drop in the laminar flow using Hagen-Poiseuille equation; and
calculating, using the computer processor, volumetric flow changes along the pump system due to the pressure drop.

3. The method of claim 2, wherein the plurality of optimal system parameters includes a volumetric flow and a final pressure.

4. The method of claim 1, wherein a plurality of pumps in the pump system may be connected in parallel or in series.

5. The method of claim 1, wherein an optimal number of pumps is determined based on the plurality of optimal system parameters.

6. The method of claim 1, wherein the maintenance operation comprises replacing pump equipment components.

7. The method of claim 1, wherein the maintenance operation comprises adjusting operating parameters of a wellbore equipment to prevent failure.

8. A non-transitory computer readable medium storing instructions executable by a computer processor, the instructions comprising functionality for:
inputting a plurality of pump system information, the pump system information including a type of pipe, a length of pipe, a diameter of pipe, a type of pipe fittings, and a type of pipe valves;
obtaining pump performance data from a plurality of sources based on the plurality of pump system information, the plurality of sources including sensor readings, operational parameters, and production rates;
obtaining a plurality of piping information based on the plurality of pump system information, wherein the plurality of piping information includes a material of pipe, a relative roughness of pipe, an effective area of pipe, and an equivalent length for the type of pipe fittings;
calculating a plurality of optimal system parameters based on a plurality of calculations based on the plurality of pump system information, the pump performance data, and the plurality of piping information; and
performing a maintenance operation in response to the calculated plurality of optimal system parameters.

9. The non-transitory computer readable medium of claim 8, wherein calculating the plurality of optimal system parameters comprises:
determining a laminar flow of liquid using Reynolds number equation;
calculating a pressure drop in the laminar flow using Hagen-Poiseuille equation; and
calculating volumetric flow changes along the pump system due to the pressure drop.

10. The non-transitory computer readable medium of claim 9, wherein the plurality of optimal system parameters includes a volumetric flow and a final pressure.

11. The non-transitory computer readable medium of claim 8, wherein a plurality of pumps in the pump system may be connected in parallel or in series.

12. The non-transitory computer readable medium of claim 8, wherein an optimal number of pumps is determined based on the plurality of optimal system parameters.

13. The non-transitory computer readable medium of claim 8, wherein the maintenance operation comprises replacing pump equipment components.

14. The non-transitory computer readable medium of claim 8, wherein the maintenance operation comprises adjusting operating parameters of a pump equipment to prevent failure.

15. A system comprising:
a plurality of sensors; and
a computer processor, wherein the computer processor is coupled to the plurality of sensors, the computer processor comprising functionality for:
inputting a plurality of pump system information, the pump system information including a type of pipe, a length of pipe, a diameter of pipe, a type of pipe fittings, and a type of pipe valves;
obtaining pump performance data from a plurality of sources based on the plurality of pump system information, the plurality of sources including sensor readings, operational parameters, and production rates;
obtaining a plurality of piping information based on the plurality of pump system information, wherein the plurality of piping information includes a material of pipe, a relative roughness of pipe, an effective area of pipe, and an equivalent length for the type of pipe fittings;
calculating a plurality of optimal system parameters based on a plurality of calculations based on the plurality of pump system information, the pump performance data, and the plurality of piping information; and
performing a maintenance operation in response to the calculated plurality of optimal system parameters.

16. The system of claim 15, wherein calculating the plurality of optimal system parameters comprises:
determining a laminar flow of liquid using Reynolds number equation;
calculating a pressure drop in the laminar flow using Hagen-Poiseuille equation; and
calculating volumetric flow changes along the pump system due to the pressure drop.

17. The system of claim 15, wherein the plurality of optimal system parameters includes a volumetric flow and a final pressure.

18. The system of claim 15, wherein a plurality of pumps in the pump system may be connected in parallel or in series.

19. The system of claim 15, wherein the maintenance operation comprises replacing pump equipment components.

20. The system of claim 15, wherein the maintenance operation comprises adjusting operating parameters of a pump equipment to prevent failure.
